(19) United States
(12) Patent Application Publication
(10) Pub. No.: US 2013/0210238 A1
(43) Pub. Date: Aug. 15, 2013

(54) Multi-Injector Spatial ALD Carousel and Methods of Use

(71) Applicant: Joseph Yudovsky, Campbell, CA (US)

(72) Inventor: Joseph Yudovsky, Campbell, CA (US)

(21) Appl. No.: 13/789,050

(22) Filed: Mar. 7, 2013

Related U.S. Application Data
(63) Continuation-in-part of application No. 13/754,733, filed on Jan. 30, 2013.
Application No. 13/754,733 is a continuation-in-part of application No. 13/754,771, filed on Jan. 30, 2013.
(60) Provisional application No. 61/593,224, filed on Jan. 31, 2012.
(60) Provisional application No. 61/593,215, filed on Jan. 31, 2012.

(51) Int. Cl. H01L 21/02

(52) U.S. Cl. CPC H01L 21/02104
USPC 438/758; 118/719

(57) ABSTRACT

A substrate processing chamber and methods for processing multiple substrates is provided and generally includes a plurality of spaced gas distribution assemblies and a substrate support apparatus to rotate substrates along a path adjacent each of the plurality of gas distribution assemblies. Each of the gas distribution assemblies comprises a plurality of elongate gas ports extending in a direction substantially perpendicularly to the path traversed by the substrate.

### CROSS-REFERENCE TO RELATED APPLICATIONS

This application is a continuation-in-part of U.S. patent application Ser. No. 13/754,733, filed Jan. 30, 2013, which claims priority to U.S. Provisional Application No. 61/593,224, filed Jan. 31, 2012, and this application is a continuation-in-part of U.S. patent application Ser. No. 13/754,771, filed Jan. 30, 2013, which claims priority to U.S. Provisional Application No. 61/593,215, filed Jan. 31, 2012.

### BACKGROUND

Embodiments of the present invention generally relate to an apparatus for processing substrates. More particularly, the invention relates to a batch processing platform for performing atomic layer deposition (ALD) and chemical vapor deposition (CVD) on substrates.

The process of forming semiconductor devices is commonly conducted in substrate processing platforms containing multiple chambers. In some instances, the purpose of a multi-chamber processing platform or cluster tool is to perform two or more processes on a substrate sequentially in a controlled environment. In other instances, however, a multiple chamber processing platform may only perform a single processing step on substrates; the additional chambers are intended to maximize the rate at which substrates are processed by the platform. In the latter case, the process performed on substrates is typically a batch process, wherein a relatively large number of substrates, e.g. 25 or 50, are processed in a given chamber simultaneously. Batch processing is especially beneficial for processes that are too time-consuming to be performed on individual substrates in an economically viable manner, such as for ALD processes and some chemical vapor deposition (CVD) processes.

The effectiveness of a substrate processing platform, or system, is often quantified by cost of ownership (COO). The COO, while influenced by many factors, is largely affected by the system footprint, i.e., the total floor space required to operate the system in a fabrication plant, and system throughput, i.e., the number of substrates processed per hour. Footprint typically includes access areas adjacent the system that are required for maintenance. Hence, although a substrate processing platform may be relatively small, if it requires access from all sides for operation and maintenance, the system's effective footprint may still be prohibitively large.

The semiconductor industry's tolerance for process variability continues to decrease as the size of semiconductor devices shrink. To meet these tighter process requirements, the industry has developed a host of new processes which meet the tighter process window requirements, but these processes often take a longer time to complete. For example, for forming a copper diffusion barrier layer conformally onto the surface of a high aspect ratio, 65 nm or smaller interconnect feature, it may be necessary to use an ALD process. ALD is a variant of CVD that demonstrates superior step coverage compared to CVD. ALD is based upon atomic layer epitaxy (ALE) that was originally employed to fabricate electroluminescent displays. ALD employs chemisorption to deposit a saturated monolayer of reactive precursor molecules on a substrate surface. This is achieved by cyclically alternating the pulsing of appropriate reactive precursors into a deposition chamber. Each injection of a reactive precursor is typically separated by an inert gas purge to provide a new atomic layer to previous deposited layers to form an uniform material layer on the surface of a substrate. Cycles of reactive precursor and inert purge gases are repeated to form the material layer to a desired thickness. The biggest drawback with ALD techniques is that the deposition rate is much lower than typical CVD techniques by at least an order of magnitude. For example, some ALD processes can require a chamber processing time from about 10 to about 200 minutes to deposit a high quality layer on the surface of the substrate. In choosing such ALD and epitaxy processes for better device performance, the cost to fabricate devices in a conventional single substrate processing chamber would increase due to very low substrate processing throughput. Hence, when implementing such processes, a continuous substrate processing approach is needed to be economically feasible.

Currently, carousel type processing systems have multiple wafers at different positions with respect to the injector. After completing deposition, every wafer has experienced a different history resulting in inter-wafer non-uniformity across the batch of wafers.

Therefore, a continuous substrate processing approach is needed to save time and improve the quality and uniformity of the deposited film.

### SUMMARY

Embodiments of the invention are directed to processing chambers comprising a plurality of gas distribution assemblies and a substrate support apparatus. The plurality of gas distribution assemblies are spaced about the processing chamber so that there is a region between each of the gas distribution assemblies. The substrate support apparatus is within the processing chamber to rotate at least one substrate along a path adjacent each of the plurality of gas distribution assemblies. Each of the gas distribution assemblies comprises a plurality of elongate gas ports extending in a direction substantially perpendicularly to the path traversed by the at least one substrate. The plurality of gas ports comprises a first reactive gas port and a second reactive gas port so that a substrate passing the gas distribution assemblies will be subjected to, in order, the first reactive gas port and the second reactive gas port to deposit a layer on the substrate.

Some embodiments further comprise a set of first treatment stations positioned between each of the plurality of gas distribution assemblies. In one or more embodiments, each of the first treatment stations providing the same type of treatment. In some embodiments, at least one of the set of first treatment stations provides a different type of treatment the at least one other of the set of first treatment stations. In one or more embodiments, each of the first set of treatment stations comprises a plasma treatment station.

Some embodiments further comprise a set of second treatment stations. Each of the second treatment stations are positioned between a gas distribution assembly and a first treatment station, so that a first treatment station is between a gas distribution assembly and a second treatment station and a second treatment station is between a first treatment station and an adjacent gas distribution assembly. In one or more embodiments, one or more of the set of first treatment stations and the set of second treatments stations comprise plasma treatment stations. In some embodiments, one of the set of first treatment stations and the set of second treatment stations comprise plasma treatment stations and the other of the set of first treatment stations and set of second treatments stations do not provide a plasma treatment.

In some embodiments, each of the gas distribution assemblies comprises a pie-shaped segment with an inner peripheral edge and an outer peripheral edge. In one or more embodiments, each of the gas ports is narrower near the inner peripheral edge and wider near the outer peripheral edge.

In some embodiments, the substrate support apparatus comprises a susceptor assembly. In one or more embodiments, the susceptor comprises a plurality of recesses sized to support a substrate. In some embodiments, the recesses are sized so that the top surface of the substrate is substantially coplanar with the top surface of the susceptor.

Additional embodiments of the invention are directed to processing chambers comprising a plurality of pie-shaped gas distribution assemblies, a set of first treatment stations and a susceptor. The plurality of pie-shaped gas distribution assemblies are spaced about the processing chamber so that there is a region between each of the gas distribution assemblies. Each of the pie-shaped gas distribution assemblies has an inner peripheral edge and an outer peripheral edge and a plurality of elongate gas ports extending from near the inner peripheral edge to near the outer peripheral edge. Each elongate gas port has a larger width at the outer peripheral edge than at the inner peripheral edge. The plurality of gas ports comprise a first reactive gas port and second reactive gas port so that a substrate passing the gas distribution assembly will be subjected to, in order, the first reactive gas port and the second reactive gas port to deposit a layer on the substrate. The set of first treatment stations are positioned between each of the pie-shaped gas distribution assemblies. The susceptor comprises a plurality of recesses to support a plurality of substrates, the susceptor to rotate substrates in a circular path adjacent each of the plurality of gas distribution assemblies and first treatment stations.

Additional embodiments of the invention are directed to cluster tools comprising a central transfer station comprising a robot to move substrates between the central transfer station and one or more of a load lock chamber and a processing chamber, and at least one processing chamber according to one or more disclosed embodiment.

Further embodiments of the invention are directed to methods of processing a plurality of substrates. A plurality of substrates are loaded onto a substrate support in a processing chamber. The substrate support is rotated to pass each of the plurality of substrates across a gas distribution assembly to deposit a film to a region between gas distribution plates. Each of the substrates are treated at the a treatment station positioned in the region between gas distribution assemblies. The steps are repeated to form a film of desired thickness.

Some embodiments further comprise rotating each of the substrates from a first treatment station to a second treatment station positioned between the first treatment station and a gas distribution assembly and treating each of the substrates at the second treatment station.

In one or more embodiments, depositing the film comprises sequentially exposing the substrates to a first reactive gas and a second reactive gas. In some embodiments, treating each of the substrates at the first treatment stations comprises exposing the substrates to a plasma. One or more embodiments further comprise heating the substrates.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional side view of a spatial atomic layer deposition chamber in accordance with one or more embodiment of the invention;

FIG. 2 shows a perspective view of a susceptor in accordance with one or more embodiments of the invention;

FIG. 3 shows a schematic of a pie-shaped gas distribution assembly in accordance with one or more embodiments of the invention;

FIG. 4 is a schematic plan view of a substrate processing system configured with four gas distribution assemblies and four first treatment stations with a loading station in accordance with one or more embodiments of the invention;

FIG. 5 is a schematic plan view of a substrate processing system configured with three gas distribution assemblies, three first treatment stations and three second treatment stations in accordance with one or more embodiments of the invention; and

FIGS. 6A through 6C shows schematic plan view of cluster tools including a plurality of processing chambers and a central transfer station in accordance with one or more embodiments of the invention.

### DETAILED DESCRIPTION

Embodiments of the invention provide a substrate processing system for continuous substrate deposition to maximize throughput and improve processing efficiency. The substrate processing system can also be used for pre-deposition and post-deposition substrate treatments.

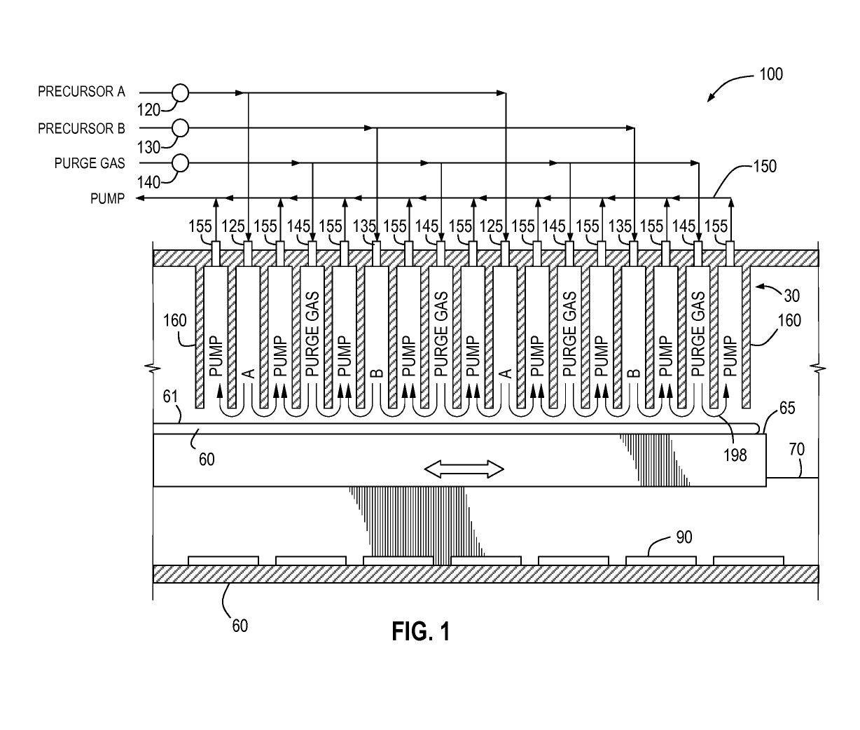

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. For example, in spatially separated ALD, described with respect to FIG. 1, each precursor is delivered to the substrate, but any individual precursor stream, at any given time, is only delivered to a portion of the substrate. Additionally, reference to depositing on a substrate can mean both a bare substrate and a substrate with one or more films or features deposited or formed thereon.

As used in this specification and the appended claims, the terms “reactive gas”, “precursor”, “reactant”, and the like, are used interchangeably to mean a gas that includes a species which is reactive in an atomic layer deposition process. For example, a first “reactive gas” may simply adsorb onto the surface of a substrate and be available for further chemical reaction with a second reactive gas.

FIG. 1 is a schematic cross-sectional view of a portion of a processing chamber 20 in accordance with one or more embodiments of the invention. The processing chamber 20 is generally a sealable enclosure, which is operated under vacuum, or at least low pressure conditions. The system 100 includes a gas distribution assembly 30 capable of distributing one or more gases across the top surface 61 of a substrate 60. The gas distribution assembly 30 can be any suitable assembly known to those skilled in the art, and specific gas distribution assemblies described should not be taken as limiting the scope of the invention. The output face of the gas distribution assembly 30 faces the first surface 61 of the substrate 60.

Substrates for use with the embodiments of the invention can be any suitable substrate. In some embodiments, the substrate is a rigid, discrete, generally planar substrate. As used in this specification and the appended claims, the term “discrete” when referring to a substrate means that the substrate has a fixed dimension. The substrate of one or more embodiments is a semiconductor substrate, such as a 200 mm or 300 mm diameter silicon substrate. In some embodiments, the substrate is one or more of silicon, silicon germanium, gallium arsenide, gallium nitride, germanium, gallium phosphide, indium phosphide, sapphire and silicon carbide.

The gas distribution assembly 30 comprises a plurality of gas ports to transmit one or more gas streams to the substrate 60 and a plurality of vacuum ports disposed between each gas port to transmit the gas streams out of the processing chamber 20. In the embodiment of FIG. 1, the gas distribution assembly 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 injects a continuous (or pulse) stream of a reactive precursor of compound A into the processing chamber 20 through a plurality of gas ports 125. The precursor injector 130 injects a continuous (or pulse) stream of a reactive precursor of compound B into the processing chamber 20 through a plurality of gas ports 135. The purge gas injector 140 injects a continuous (or pulse) stream of a non-reactive or purge gas into the processing chamber 20 through a plurality of gas ports 145. The purge gas removes reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, thereby avoiding cross-contamination between the precursors.

In another aspect, a remote plasma source (not shown) may be connected to the precursor injector 120 and the precursor injector 130 prior to injecting the precursors into the processing chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high energy light source (e.g., UV energy), or exposure to an x-ray source. Exemplary remote plasma sources are available from vendors such as MKS Instruments, Inc. and Advanced Energy Industries, Inc.

The system 100 further includes a pumping system 150 connected to the processing chamber 20. The pumping system 150 is generally configured to evacuate the gas streams out of the processing chamber 20 through one or more vacuum ports 155. The vacuum ports 155 are disposed between each gas port so as to evacuate the gas streams out of the processing chamber 20 after the gas streams react with the substrate surface and to further limit cross-contamination between the precursors.

The system 100 includes a plurality of partitions 160 disposed on the processing chamber 20 between each port. A lower portion of each partition extends close to the first surface 61 of substrate 60, for example, about 0.5 mm or greater from the first surface 61. In this manner, the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the invention. It will be understood by those skilled in the art that the gas distribution system shown is merely one possible distribution system and the other types of showerheads and gas distribution assemblies may be employed.

Atomic layer deposition systems of this sort (i.e., where multiple gases are separately flowed toward the substrate at the same time) are referred to as spatial ALD. In operation, a substrate 60 is delivered (e.g., by a robot) to the processing chamber 20 and can be placed on a shuttle 65 before or after entry into the processing chamber. The shuttle 65 is moved along the track 70, or some other suitable movement mechanism, through the processing chamber 20, passing beneath (or above) the gas distribution assembly 30. In the embodiment shown in FIG. 1, the shuttle 65 is moved in a linear path through the chamber. FIG. 3, as explained further below, shows an embodiment in which wafers are moved in a circular path through a carousel processing system.

Referring back to FIG. 1, as the substrate 60 moves through the processing chamber 20, the first surface 61 of substrate 60 is repeatedly exposed to the reactive gas A coming from gas ports 125 and reactive gas B coming from gas ports 135, with the purge gas coming from gas ports 145 in between. Injection of the purge gas is designed to remove unreacted material from the previous precursor prior to exposing the substrate surface 110 to the next precursor. After each exposure to the various gas streams (e.g., the reactive gases or the purge gas), the gas streams are evacuated through the vacuum ports 155 by the pumping system 150. Since a vacuum port may be disposed on both sides of each gas port, the gas streams are evacuated through the vacuum ports 155 on both sides. Thus, the gas streams flow from the respective gas ports vertically downward toward the first surface 61 of the substrate 60, across the substrate surface 110 and around the lower portions of the partitions 160, and finally upward toward the vacuum ports 155. In this manner, each gas may be uniformly distributed across the substrate surface 110. Arrows 198 indicate the direction of the gas flow. Substrate 60 may also be rotated while being exposed to the various gas streams. Rotation of the substrate may be useful in preventing the formation of strips in the formed layers. Rotation of the substrate can be continuous or in discrete steps and can occur while the substrate is passing beneath the gas distribution assembly 30 or when the substrate is in a region before and/or after the gas distribution assembly 30.

Sufficient space is generally provided after the gas distribution assembly 30 to ensure complete exposure to the last gas port. Once the substrate 60 has completely passed beneath the gas distribution assembly 30, the first surface 61 has completely been exposed to every gas port in the processing chamber 20. The substrate can then be transported back in the opposite direction or forward. If the substrate 60 moves in the opposite direction, the substrate surface may be exposed again to the reactive gas A, the purge gas, and reactive gas B, in reverse order from the first exposure.

The extent to which the substrate surface 110 is exposed to each gas may be determined by, for example, the flow rates of each gas coming out of the gas port and the rate of movement of the substrate 60. In one embodiment, the flow rates of each gas are controlled so as not to remove adsorbed precursors from the substrate surface 61. The width between each partition, the number of gas ports disposed on the processing chamber 20, and the number of times the substrate is passed across the gas distribution assembly may also determine the extent to which the substrate surface 61 is exposed to the various gases. Consequently, the quantity and quality of a deposited film may be optimized by varying the above-referenced factors.

Although description of the process has been made with the gas distribution assembly 30 directing a flow of gas downward toward a substrate positioned below the gas distribution assembly, it will be understood that this orientation can be different. In some embodiments, the gas distribution assembly 30 directs a flow of gas upward toward a substrate surface. As used in this specification and the appended claims, the term “passed across” means that the substrate has been moved from one side of the gas distribution assembly to the other side so that the entire surface of the substrate is exposed to each gas stream from the gas distribution plate. Absent additional description, the term “passed across” does not imply any particular orientation of gas distribution assemblies, gas flows or substrate positions.

In some embodiments, the shuttle 65 is a susceptor 66 for carrying the substrate 60. Generally, the susceptor 66 is a carrier which helps to form a uniform temperature across the substrate. The susceptor 66 is movable in both directions (left-to-right and right-to-left, relative to the arrangement of FIG. 1) or in a circular direction (relative to FIG. 3). The susceptor 66 has a top surface 67 for carrying the substrate 60. The susceptor 66 may be a heated susceptor so that the substrate 60 may be heated for processing. As an example, the susceptor 66 may be heated by radiant heat lamps 90, a heating plate, resistive coils, or other heating devices, disposed underneath the susceptor 66.

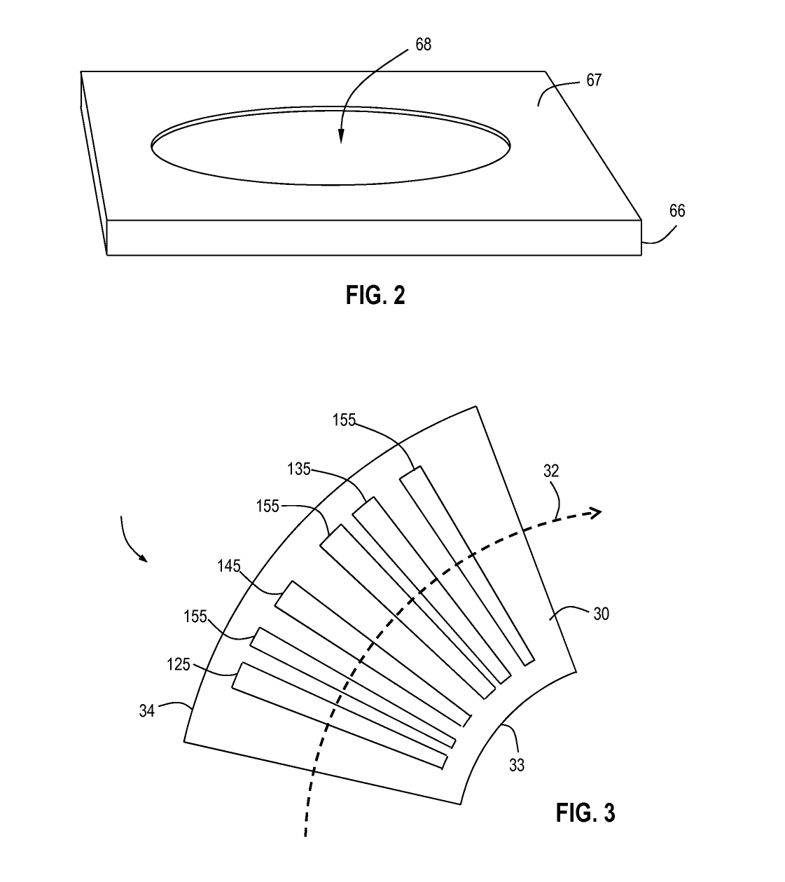

In still another embodiment, the top surface 67 of the susceptor 66 includes a recess 68 to accept the substrate 60, as shown in FIG. 2. The susceptor 66 is generally thicker than the thickness of the substrate so that there is susceptor material beneath the substrate. In some embodiments, the recess 68 is sized such that when the substrate 60 is disposed inside the recess 68, the first surface 61 of substrate 60 is level with, or substantially coplanar with, the top surface 67 of the susceptor 66. Stated differently, the recess 68 of some embodiments is sized such that when a substrate 60 is disposed therein, the first surface 61 of the substrate 60 does not protrude above the top surface 67 of the susceptor 66. As used in this specification and the appended claims, the term “substantially coplanar” means that the top surface of the wafer and the top surface of the susceptor assembly are coplanar within ±0.2 mm. In some embodiments, the top surfaces are coplanar within ±0.15 mm, ±0.10 mm or ±0.05 mm.

FIG. 1 shows a cross-sectional view of a processing chamber in which the individual gas ports are shown. This embodiment can be either a linear processing system in which the width of the individual gas ports is substantially the same across the entire width of the gas distribution plate, or a pie-shaped segment in which the individual gas ports change width to conform to the pie shape. FIG. 3 shows a portion of a pie-shaped gas distribution assembly 30. A substrate would be passed across this gas distribution assembly 30 in an arc shape path 32. Each of the individual gas ports 125, 135, 145, 155 have a narrower width near the inner peripheral edge 33 of the gas distribution assembly 30 a and a larger width near the outer peripheral edge 34 of the gas distribution assembly 30. The shape or aspect ratio of the individual ports can be proportional to, or different from, the shape or aspect ratio of the gas distribution assembly 30 segment. In some embodiments, the individual ports are shaped so that each point of a wafer passing across the gas distribution assembly 30 following path 32 would have about the same residence time under each gas port. The path of the substrates can be perpendicular to the gas ports. In some embodiments, each of the gas distribution assemblies comprise a plurality of elongate gas ports which extend in a direction substantially perpendicular to the path traversed by a substrate. As used in this specification and the appended claims, the term “substantially perpendicular” means that the general direction of movement is approximately perpendicular to the axis of the gas ports. For a pie-shaped gas port, the axis of the gas port can be considered to be a line defined as the mid-point of the width of the port extending along the length of the port.

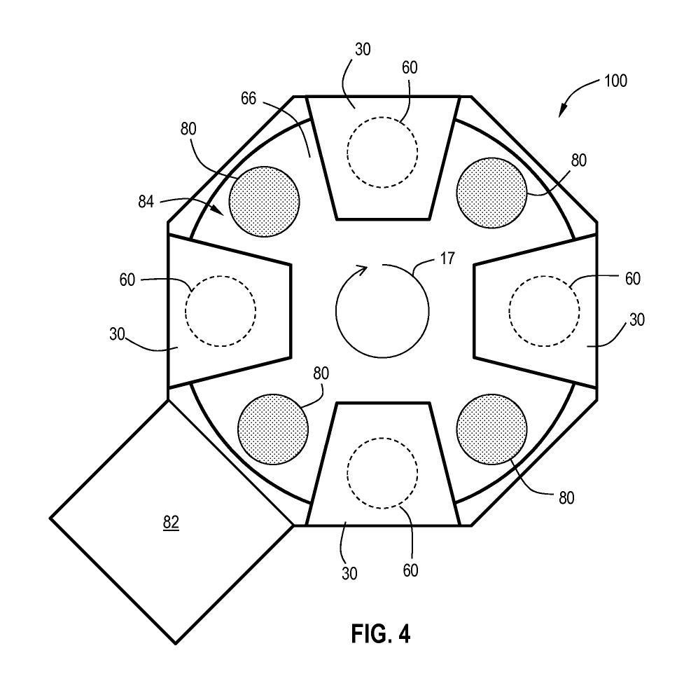

Processing chambers having multiple gas injectors can be used to process multiple wafers simultaneously so that the wafers experience the same process flow. For example, as shown in FIG. 4, the processing chamber 100 has four gas injector assemblies 30 and four wafers 60. At the outset of processing, the wafers 60 can be positioned between the injector assemblies 30. Rotating the susceptor 66 of the carousel by 45° will result in each wafer 60 being moved to an injector assembly 30 for film deposition. This is the position shown in FIG. 4. An additional 45° rotation would move the wafers 60 away from the injector assemblies 30. With spatial ALD injectors, a film is deposited on the wafer during movement of the wafer relative to the injector assembly. In some embodiments, the susceptor 66 is rotated so that the wafers 60 do not stop beneath the injector assemblies 30. The number of wafers 60 and gas distribution assemblies 30 can be the same or different. In some embodiments, there are the same number of wafers being processed as there are gas distribution assemblies. In one or more embodiments, the number of wafers being processed are an integer multiple of the number of gas distribution assemblies. For example, if there are four gas distribution assemblies, there are 4x wafers being processed, where x is an integer value greater than or equal to one.

The processing chamber 100 shown in FIG. 4 is merely representative of one possible configuration and should not be taken as limiting the scope of the invention. Here, the processing chamber 100 includes a plurality of gas distribution assemblies 30. In the embodiment shown, there are four gas distribution assemblies 30 evenly spaced about the processing chamber 100. The processing chamber 100 shown is octagonal, however, it will be understood by those skilled in the art that this is one possible shape and should not be taken as limiting the scope of the invention. The gas distribution assemblies 30 shown are rectangular, but it will be understood by those skilled in the art that the gas distribution assemblies can be pie-shaped segments, like that shown in FIG. 3.

The processing chamber 100 includes a substrate support apparatus, shown as a round susceptor 66 or susceptor assembly. The substrate support apparatus, or susceptor 66, is capable of moving a plurality of substrates 60 beneath each of the gas distribution assemblies 30. A load lock 82 might be connected to a side of the processing chamber 100 to allow the substrates 60 to be loaded/unloaded from the chamber 100.

The processing chamber 100 includes a plurality, or set, of first treatment stations 80 positioned between each of the plurality of gas distribution assemblies 30. In some embodiments, each of the first treatment stations 80 provides the same treatment to a substrate 60. The number of first treatment stations is equal to an integer multiple of the number of gas distribution assemblies 30. For example, if there are four gas distribution assemblies 30, then there are 4x first treatment stations 80, where x is an integer value greater than or equal to one.

The number of different types of treatment stations can vary depending on the process. For example, there can be one, two, three, four, five, six, seven or more sets of treatment stations positioned between the gas distribution assemblies 30. Each set of treatment stations can provide a different treatment from every other set of treatments stations, or there can be a mixture of the same type and different types of treatments. In some embodiments, one or more of the individual treatments stations provides a different treatment than one or more of the other individual treatment stations. In some embodiments, one of the set of first treatment stations and the set of second treatment stations comprise plasma treatment stations and the other of the set of first treatment stations and set of second treatments stations do not provide a plasma treatment.

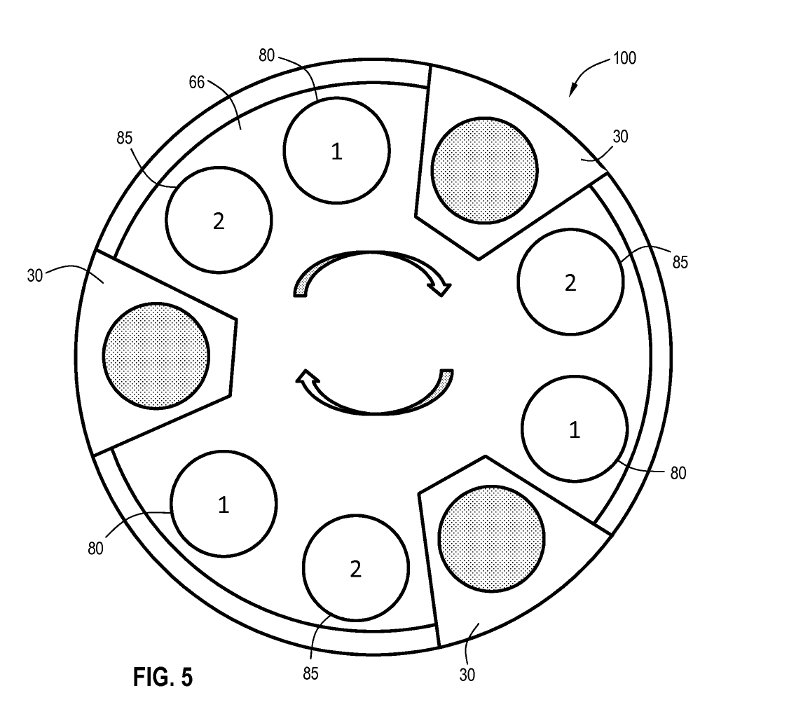

In the embodiment shown in FIG. 5, a set of second treatment stations 85 are positioned between the first treatment stations 80 and the gas distribution assemblies 30 so that a substrate 60 rotated through the processing chamber 100 would encounter, depending on where the substrate 60 starts, a gas distribution assembly 30, a first treatment station 80 and a second treatment station 85 before encountering a second of any of these. For example, as shown in FIG. 5, if the substrate started at the first treatment station 80, it would see, in order, the first treatment station 80, a gas distribution assembly 30 and a second treatment station 85 before encountering a second first treatment station 85.

Additional processing apparatus can also be positioned between the injectors. For example, UV lamps, flash lamps, plasma sources and heaters. The wafers are then moved between positions with the gas distribution assemblies 30 to a position with, for example, a showerhead delivering plasma to the wafer. The plasma station being referred to as a treatment station 80. In one or more example, silicon nitride films can be formed with plasma treatment after each deposition layer. As the ALD reaction is, theoretically, self-limiting as long as the surface is saturated, additional exposure to the deposition gas will not cause damage to the film.

Rotation of the carousel can be continuous or discontinuous. In continuous processing, the wafers are constantly rotating so that they are exposed to each of the injectors in turn. In discontinuous processing, the wafers can be moved to the injector region and stopped, and then to the region 84 between the injectors and stopped. For example, the carousel can rotate so that the wafers move from an inter-injector region across the injector (or stop adjacent the injector) and on to the next inter-injector region where it can pause again. Pausing between the injectors may provide time for additional processing steps between each layer deposition (e.g., exposure to plasma).

The embodiment shown in FIG. 5 is an example of a processing chamber 100 in which, there are a different number of wafers 60 than gas distribution assemblies 30 maintaining a symmetrical distribution. For example, the processing chamber 100 shown has three gas distribution assemblies 30 and six wafers 60. At any given point during processing, the combination of gas distribution assemblies 30, wafer, 60 and treatment stations 80, 85 are three-fold symmetrical (because there are three of each) about a central axis of the processing chamber 100. Initially, none of the wafers are positioned under the gas distribution assemblies 30; rotation of the carousel 30° would place the first set of wafers 1 under the gas distribution assemblies 30 and move the second set of wafers 2 into a position immediately preceding the gas distribution assemblies 30. The next 30° rotation would move the first set of wafers 1 out from under the gas distribution assemblies 30 and the second set of wafers 2 to the gas distribution assemblies 30 region. Again, the substrates can be exposed to additional processing steps between each gas distribution assemblies 30.

The gas distribution plates 30 can have gas ports that are substantially parallel or wedge shaped. Once the surface reactions are saturated, it does not matter if the wafer spends additional time adjacent the gas ports as no additional reaction will take place.

In some embodiments, the processing chamber comprises a plurality of gas curtains 40. Each gas curtain 40 creates a barrier to prevent, or minimize, the movement of processing gases from the gas distribution assemblies 30 from migrating from the gas distribution assembly regions and gases from the treatment stations 80 from migrating from the treatment station regions. The gas curtain 40 can include any suitable combination of gas and vacuum streams which can isolate the individual processing sections from the adjacent sections. In some embodiments, the gas curtain 40 is a purge (or inert) gas stream. In one or more embodiments, the gas curtain 40 is a vacuum stream that removes gases from the processing chamber. In some embodiments, the gas curtain 40 is a combination of purge gas and vacuum streams so that there are, in order, a purge gas stream, a vacuum stream and a purge gas stream. In one or more embodiments, the gas curtain 40 is a combination of vacuum streams and purge gas streams so that there are, in order, a vacuum stream, a purge gas stream and a vacuum stream. The gas curtains 40 shown in FIG. 4 are positioned between each of the gas distribution assemblies 30 and treatment stations 80, but it will be understood that the curtains can be positioned at any point or points along the processing path.

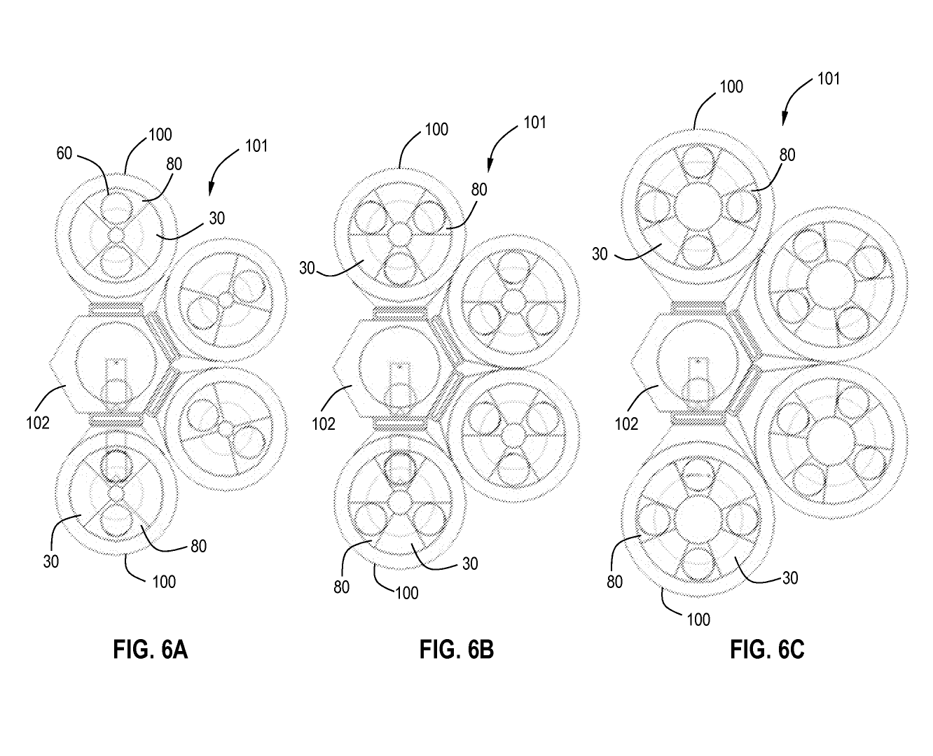

FIGS. 6A through 6C show different embodiments of cluster tools 101 with multiple carousel type processing chambers 100. The embodiment shown in FIG. 6A has four processing chambers 100 around a central transfer station 102. Each of the processing chambers 100 includes two gas distribution assemblies 30 and two first treatment stations 80. The embodiment of FIG. 6B has three gas distribution assemblies 30 and three first treatment stations 80 and the embodiment of FIG. 6C has four gas distribution assemblies 30 and four first treatments stations 80. Other numbers of injectors, or gas distribution assemblies 30, can be employed as well. In some embodiments, the number of gas distribution assemblies 30 is equal to the number of wafers 60 that can be processed simultaneously. Each wafer 60 is either under the gas distribution assembly 30 (or moving under the gas distribution assembly 30) or in the region 84 between the gas distribution assemblies 30 so that each wafer 60 has the same experience (i.e., experiences the same conditions and history) during processing.

Referring to FIG. 4, one or more embodiments of the invention are directed to methods of processing a plurality of substrates 60. Each of the plurality of substrates 60 is loaded into the processing chamber 100 so that each substrate 60 is in an relatively identical position as the other substrates 60. As used in this specification and the appended claims, the term “relatively identical”, “relatively the same”, “substantially equal starting positions” and the like, mean that the substrates are in equivalent positions (e.g., each under a gas distribution assembly or each between gas distribution assemblies). For example, each substrate 60 in FIG. 4 is shown positioned under a gas distribution assembly 30. Therefore, each substrate 60 has substantially equal starting positions as the other substrates 60. The plurality of substrates 60 are positioned on a substrate support apparatus which may include track portions and/or support structures. The substrate support apparatus shown in FIG. 4 is a susceptor 66 which rotates the substrates 60 around a central axis in a circle 17, or similar shape. Upon rotation, the substrates 60 move from their initial position to a next position which may be under the first treatment stations 80. When the gas distribution assemblies 30 are spatial atomic layer deposition apparatus, like that shown and described in FIG. 1, the movement under the gas distribution assembly 30 causes each portion of the substrate 60 to be exposed to a series of process gases (also referred to as precursor gases or reactive gases, and the like) to deposit a layer on the substrate surface. The substrate then moves to the first treatment station 80 where it is subjected to a post-deposition process. In some embodiments, the post-deposition process is one or more of annealing, UV exposure, heating and plasma treatment.

The substrates are moved either in a continuous uninterrupted manner or in discrete steps. When moved in discrete steps, the substrates may be moved from a first treatment station across the gas distribution assembly 30 area to another first treatment station 80. This allows the movement of the substrate to cause the sequential exposure of the different reaction gases adjacent the gas distribution assembly to deposit the film.

In some embodiments, alternating gas distribution assemblies provide different reaction gases and the alternating first treatment stations provide a different treatment. For example, the first gas distribution assembly may supply a first reactive gas to the substrate surface to form a partial film on the surface, the substrate can then move to a first treatment station where the partial film is heated and then moved to the second gas distribution assembly where a second reactive gas reacts with the partial film to form a complete film followed by moving the substrate to another first treatment station where the film is exposed to a plasma to, for example, densify the film. In this configuration, a full cycle on the embodiment of FIG. 4 would result in the deposition of two layers.

In some embodiments, one or more layers may be formed during a plasma enhanced atomic layer deposition (PEALD) process. In some processes, the use of plasma provides sufficient energy to promote a species into the excited state where surface reactions become favorable and likely. Introducing the plasma into the process can be continuous or pulsed. In some embodiments, sequential pulses of precursors (or reactive gases) and plasma are used to process a layer. In some embodiments, the reagents may be ionized either locally (i.e., within the processing area) or remotely (i.e., outside the processing area). In some embodiments, remote ionization can occur upstream of the deposition chamber such that ions or other energetic or light emitting species are not in direct contact with the depositing film. In some PEALD processes, the plasma is generated external from the processing chamber, such as by a remote plasma generator system. The plasma may be generated via any suitable plasma generation process or technique known to those skilled in the art. For example, plasma may be generated by one or more of a microwave (MW) frequency generator or a radio frequency (RF) generator. The frequency of the plasma may be tuned depending on the specific reactive species being used. Suitable frequencies include, but are not limited to, 2 MHz, 13.56 MHz, 40 MHz, 60 MHz and 100 MHz. Although plasmas may be used during the deposition processes disclosed herein, it should be noted that plasmas may not be required. Indeed, other embodiments relate to deposition processes under very mild conditions without a plasma.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the desired separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus is disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

During processing, the substrate can be heated or cooled. Such heating or cooling can be accomplished by any suitable means including, but not limited to, changing the temperature of the substrate support (e.g., susceptor) and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposure to different reactive or purge gases. Rotating the substrate during processing (either continuously or in steps) may help produce a more uniform deposition or etch by minimizing the effect of, for example, local variability in gas flow geometries.

While the foregoing is directed to embodiments of the present invention, other and further embodiments of the invention may be devised without departing from the basic scope thereof, and the scope thereof is determined by the claims that follow.

What is claimed is:

1. A processing chamber comprising:
a plurality of gas distribution assemblies spaced about the processing chamber so that there is a region between each of the gas distribution assemblies; and
a substrate support apparatus within the processing chamber, the substrate support apparatus to rotate at least one substrate along a path adjacent each of the plurality of gas distribution assemblies,
wherein each of the gas distribution assemblies comprises a plurality of elongate gas ports extending in a direction substantially perpendicularly to the path traversed by the at least one substrate, the plurality of gas ports comprising a first reactive gas port and a second reactive gas port so that a substrate passing the gas distribution assemblies will be subjected to, in order, the first reactive gas port and the second reactive gas port to deposit a layer on the substrate.

2. The processing chamber of claim 1, further comprising a set of first treatment stations positioned between each of the plurality of gas distribution assemblies.

3. The processing chamber of claim 2, wherein each of the first treatment stations providing the same type of treatment.

4. The processing chamber of claim 2, wherein at least one of the set of first treatment stations provides a different type of treatment the at least one other of the set of first treatment stations.

5. The processing chamber of claim 2, wherein each of the first set of treatment stations comprises a plasma treatment station.

6. The processing chamber of claim 2, further comprising a set of second treatment stations, each of the second treatment stations positioned between a gas distribution assembly and a first treatment station, so that a first treatment station is between a gas distribution assembly and a second treatment station and a second treatment station is between a first treatment station and an adjacent gas distribution assembly.

7. The processing chamber of claim 6, wherein one or more of the set of first treatment stations and the set of second treatments stations comprise plasma treatment stations.

8. The processing chamber of claim 6, wherein one of the set of first treatment stations and the set of second treatment stations comprise plasma treatment stations and the other of the set of first treatment stations and set of second treatments stations do not provide a plasma treatment.

9. The processing chamber of claim 1, wherein each of the gas distribution assemblies comprises a pie-shaped segment with an inner peripheral edge and an outer peripheral edge.

10. The processing chamber of claim 9, wherein each of the gas ports is narrower near the inner peripheral edge and wider near the outer peripheral edge.

11. The processing chamber of claim 1, wherein the substrate support apparatus comprises a susceptor assembly.

12. The processing chamber of claim 11, wherein the susceptor comprises a plurality of recesses sized to support a substrate.

13. The processing chamber of claim 12, wherein the recesses are sized so that a top surface of the substrate is substantially coplanar with a top surface of the susceptor.

14. A processing chamber comprising:
a plurality of pie-shaped gas distribution assemblies spaced about the processing chamber so that there is a region between each of the gas distribution assemblies, each of the pie-shaped gas distribution assemblies having an inner peripheral edge and an outer peripheral edge and a plurality of elongate gas ports extending from near the inner peripheral edge to near the outer peripheral edge and having a larger width at the outer peripheral edge than at the inner peripheral edge, the plurality of gas ports comprising a first reactive gas port and second reactive gas port so that a substrate passing the gas distribution assembly will be subjected to, in order, the first reactive gas port and the second reactive gas port to deposit a layer on the substrate;
a set of first treatment stations so that a first treatment station is positioned between each of the pie-shaped gas distribution assemblies; and
a susceptor comprising a plurality of recesses to support a plurality of substrates, the susceptor to rotate substrates in a circular path adjacent each of the plurality of gas distribution assemblies and first treatment stations.

15. A cluster tool comprising:
a central transfer station comprising a robot to move substrates between the central transfer station and one or more of a load lock chamber and a processing chamber; and
at least one processing chamber according to claim 14.

16. A method of processing a plurality of substrates, the method comprising:
(a) loading a plurality of substrates onto a substrate support in a processing chamber;
(b) rotating the substrate support to pass each of the plurality of substrates across a gas distribution assembly to deposit a film to a region between gas distribution plates; and
(c) treating each of the substrates at a first treatment station positioned in the region between gas distribution plates; and
(d) repeated (b) and (c) to form a film of desired thickness.

17. The method of claim 16, further comprising:
(c1) rotating each of the substrates from a first treatment station to a second treatment station positioned between the first treatment station and a gas distribution assembly; and
(c2) treating each of the substrates at the second treatment station.

18. The method of claim 16, wherein forming the film comprises sequentially exposing the substrates to a first reactive gas and a second reactive gas.

19. The method of claim 16, wherein treating each of the substrates at the first treatment stations comprises exposing the substrates to a plasma.

20. The method of claim 16, further comprising heating the substrates.
